(19) United States
(12) Patent Application Publication
(10) Pub. No.: US 2018/0350974 A1
(43) Pub. Date: Dec. 6, 2018

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hideki Okumura, Nonoichi Ishikawa (JP); Syotaro Ono, Kanazawa Ishikawa (JP); Naoki Kusunoki, Isehara Kanagawa (JP); Shingo Sato, Kanazawa Ishikawa (JP)

(21) Appl. No.: 15/830,809

(22) Filed: Dec. 4, 2017

(30) Foreign Application Priority Data
Jun. 2, 2017 (JP) 2017-110038

(51) Int. Cl. H01L 29/78; H01L 29/06; H01L 29/40

(52) U.S. Cl. CPC H01L 29/7811; H01L 29/408; H01L 29/407; H01L 29/0634

(57) ABSTRACT

According to one embodiment, the insulating film is provided on a side surface of a second semiconductor layer located at an end in the lateral direction of the second semiconductor layers, or a side surface of a third semiconductor layer located at an end in the lateral direction of the third semiconductor layers. The semiconductive film is provided on a side surface of the insulating film. The semiconductive film is electrically connected to the first electrode and the second electrode. The semiconductive film has a resistivity higher than a resistivity of one of the second semiconductor layers and a resistivity of one of the third semiconductor layers, and lower than a resistivity of the insulating film.

### CROSS-REFERENCE TO RELATED APPLICATION

This application is based upon and claims the benefit of priority from Japanese Patent Application No. 2017-110038, filed on Jun. 2, 2017; the entire contents of which are incorporated herein by reference.

### FIELD

Embodiments described herein relate generally to a semiconductor device.

### BACKGROUND

A vertical device having a periodic arrangement structure of P-type pillar layers and N-type pillar layers called a super junction structure has been known as, for example, a semiconductor device (a power device) for power control. The super junction structure is a structure for making the charge amount (impurity amount) included in the P-type pillar layer and the charge amount included in the N-type pillar layer roughly equal to each other to thereby completely deplete the drift region to keep the high breakdown voltage while designing the impurity concentration to be higher than the impurity concentration for obtaining the same breakdown voltage, and at the same time, making a current flow through the N-type pillar layer doped with impurities to thereby realize a low ON-resistance.

### BRIEF DESCRIPTION OF THE DRAWINGS

FIG. 1 is a schematic cross-sectional view of a semiconductor device according to an embodiment;

FIG. 2 is a schematic plan view of the semiconductor device according to the embodiment;

FIG. 3 is a schematic cross-sectional view of a semiconductor device according to the embodiment;

FIG. 4A to FIG. 5B are schematic plan views of the semiconductor device according to the embodiment; and

FIG. 6A is a schematic cross-sectional view of a model used for a breakdown voltage simulation of a super junction structure, and FIG. 6B is a graph showing a tendency of an end-cut-position dependency of a breakdown voltage in the model shown in FIG. 6A.

### DETAILED DESCRIPTION

According to one embodiment, a semiconductor device includes a first electrode, a second electrode, a first semiconductor layer having a first conductivity type, a plurality of second semiconductor layers having the first conductivity type, a plurality of third semiconductor layers having a second conductivity type, a fourth semiconductor layer having the second conductivity type, a fifth semiconductor layer having the first conductivity type, a gate electrode, a gate insulating film, an insulating film, and a semiconductive film. The first semiconductor layer is provided on the first electrode. The second semiconductor layers are provided on the first semiconductor layer. The second semiconductor layers extend in a vertical direction connecting the first electrode and the second electrode. The third semiconductor layers extend in the vertical direction on the first semiconductor layer. The third semiconductor layers are adjacent to the second semiconductor layers in a lateral direction crossing the vertical direction. The fourth semiconductor layer is provided on the third semiconductor layer. The fifth semiconductor layer is provided on a surface of the fourth semiconductor layer. The fifth semiconductor layer is connected to the second electrode. The gate electrode is opposed to the fourth semiconductor layer. The gate insulating film is provided between the fourth semiconductor layer and the gate electrode. The insulating film is provided on a side surface of a second semiconductor layer located at an end in the lateral direction of the second semiconductor layers, or a side surface of a third semiconductor layer located at an end in the lateral direction of the third semiconductor layers. The semiconductive film is provided on a side surface of the insulating film. The semiconductive film is electrically connected to the first electrode and the second electrode. The semiconductive film has a resistivity higher than a resistivity of one of the second semiconductor layers and a resistivity of one of the third semiconductor layers, and lower than a resistivity of the insulating film.

The embodiment will hereinafter be described with reference to the drawings. It should be noted that in the drawings, the same elements are denoted by the same reference symbols.

Although in the following embodiment, the description will be presented assuming a first conductivity type as N-type and a second conductivity type as P-type, it is also possible to assume the first conductivity type as P-type and the second conductivity type as N-type.

Further, although in the embodiment, it is assumed that the semiconductor material is silicon, the semiconductor material is not limited to silicon, but can also be, for example, silicon carbide, gallium nitride, or gallium oxide.

Further, in the following embodiment, the impurity concentration can be replaced with the carrier concentration in the description. The carrier concentration can be regarded as an effective impurity concentration.

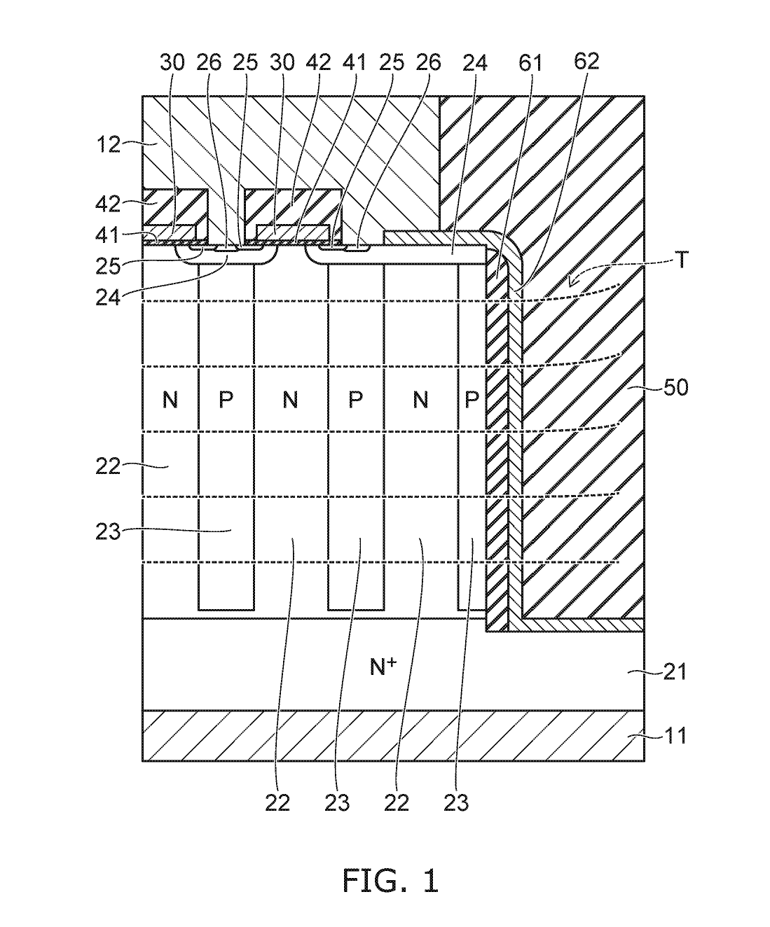

FIG. 1 is a schematic cross-sectional view of a semiconductor device according to the embodiment. FIG. 1 shows a cross-section of a part on a termination side of the semiconductor device.

The semiconductor device according to the embodiment is a vertical semiconductor device, in which a semiconductor layer is provided between a drain electrode 11 as a first electrode and a source electrode 12 as a second electrode, and in which a current flows in a direction (a vertical direction) connecting the drain electrode 11 and the source electrode 12 to each other.

The semiconductor layer is a silicon layer doped with impurities, and has an N⁺-type drain layer 21, N-type pillar layers 22, P-type pillar layers 23, P-type base layer 24, and N⁺-type source layers 25.

The N-type impurity concentration of the drain layer 21 and the source layers 25 is higher than the N-type impurity concentration of the N-type pillar layers 22.

The drain layer 21 as a first semiconductor layer is provided on the drain electrode 11 as the first electrode, and has contact with the drain electrode 11.

On the drain layer 21, there is provided the super junction structure having a plurality of N-type pillar layers 22 as a second semiconductor layer, and a plurality of P-type pillar layers 23 as a third semiconductor layer.

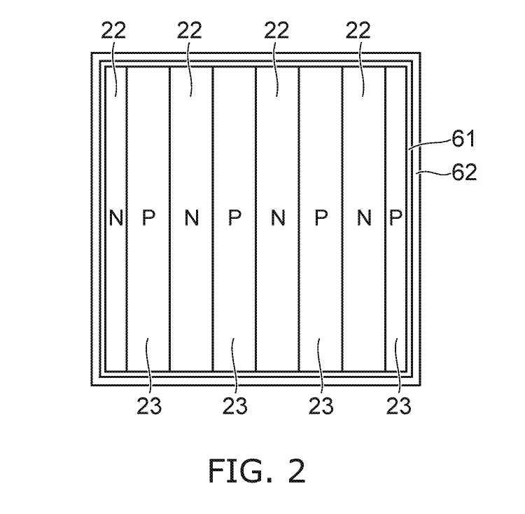

FIG. 2 shows an example of a planar layout of the super junction structure.

As shown in FIG. 1, the N-type pillar layers 22 extend in the vertical direction, and have contact with the drain layer 21. The P-type pillar layers 23 also extend in the vertical direction. It is possible, but not required, for the P-type pillar layers 23 to have contact with the drain layer 21.

The N-type pillar layer 22 and the P-type pillar layer 23 are adjacent to each other in a lateral direction (a direction parallel to a principal surface of the drain layer 21) crossing the vertical direction described above to form a P-N junction.

The N-type pillar layers 22 and the P-type pillar layers 23 are alternately arranged in the lateral direction, and the super junction structure has the periodic arrangement structure of the plurality of N-type pillar layers 22 and the P-type pillar layers 23.

As shown in FIG. 2, the N-type pillar layers 22 and the P-type pillar layers 23 extend in a direction crossing (e.g., a direction perpendicular to) the periodic arrangement direction to form a stripe.

As shown in FIG. 1, the base layers 24 as a fourth semiconductor layer are each provided on the P-type pillar layer 23. The base layers 24 each spread to a part of the N-type pillar layer 22. The base layer 24 on the termination side extends to the end without stopping in the region of the N-type pillar layer 22.

On the surface of each of the base layers 24, the source layer 25 as the fifth semiconductor layer is selectively provided. Further, on the surface of each of the base layers 24, there is provided a base contact layer 26 of P⁺-type higher in P-type impurity concentration than the base layer 24.

A gate insulating film 41 is provided on a part of the upper surface of the source layer 25, the upper surface of the N-type pillar layer 22, and the upper surface of the base layer 24 between the N-type pillar layer 22 and the source layer 25. On the gate insulating film 41, there is provided a gate electrode 30.

The gate electrode 30 is covered with an inter-layer insulating film 42. The source electrode 12 as the second electrode is provided so as to cover the inter-layer insulating film 42. The source electrode 12 has contact with the source layers 25 and the base contact layers 26.

In the example shown in FIG. 2, the P-type pillar layer 23 is disposed at the right end in the periodic arrangement direction (the lateral direction) of the super junction structure, and the N-type pillar layer 22 is disposed at the left end. FIG. 1 shows a vertical cross-section in the vicinity of the right end where the P-type pillar layer 23 is disposed.

On the side surface of the P-type pillar layer 23 at the end, there is provided an insulating film 61. The insulating film 61 is a silicon oxide film (SiO₂ film) formed by, for example, a thermal oxidation method. The lower end of the insulating film 61 reaches the drain layer 21.

As shown in FIG. 2, the insulating film 61 is also provided on the side surface of the N-type pillar layer 22 at the left end. The insulating film 61 continuously surrounds the region of the super junction structure.

A semiconductive film 62 is provided on a side surface of the insulating film 61. As shown in FIG. 2, the semiconductive film 62 continuously surrounds the region of the super junction structure.

The semiconductive film 62 has resistivity higher than the resistivity of the N-type pillar layer 22 and the resistivity of the P-type pillar layer 23, and lower than the resistivity of the insulating film 61. The semiconductive film 62 is, for example, a SInSiN (Semi-Insulated Silicon Nitride) film having the resistivity of 10⁷ through 10¹⁰ (Ωcm). The silicon composition ratio in the SInSiN film is higher than the silicon composition ratio in Si₃N₄. Alternatively, the semiconductive film 62 is a SIPOS (Semi-Insulated POlycrystalline Silicon) film.

As shown in FIG. 1, the semiconductive film 62 is provided so as to have contact with the surface of the outermost base layer 24 on the side closest to the end, and also has electrical contact with the source electrode 12. Further, the semiconductive film 62 also has contact with the drain layer 21. Therefore, the semiconductive film 62 is electrically connected to the drain electrode 11 and the source electrode 12.

Before forming the insulating film 61 and the semiconductive film 62, a trench T reaching the drain layer 21 is formed in a semiconductor layer above the drain layer 21. The trench T continuously surrounds the region of the super junction structure.

Then, the insulating film 61 is conformally formed along the sidewall (a side surface of the P-type pillar layer 23 or a side surface of the N-type pillar layer 22) of the trench T and the bottom (a surface of the drain layer 21) of the trench T.

After removing the insulating film 61 on the bottom of the trench T using, for example, an RIE (Reactive Ion Etching) method, the semiconductive film 62 is conformally formed along the surface of the outermost base layer 24, the side surface of the insulating film 61 in the trench T, and the bottom of the trench T. The semiconductive film 62 has contact with the surface of the outermost base layer 24, and the surface of the drain layer 21 on the bottom of the trench T.

In the subsequent packaging process, the trench T is filled with resin 50. The resin 50 covers the side surface of the semiconductive film 62 and the surface of the semiconductive film 62 on the drain layer 21.

In the semiconductor device described hereinabove, a potential difference is applied between the drain electrode 11 and the source electrode 12. The potential applied to the drain electrode 11 is higher than the potential applied to the source electrode 12.

During the ON operation period of the semiconductor device, a potential equal to or higher than a threshold value is applied to the gate electrode 30, and a reverse layer (an N-type channel) is formed in the region opposed to the gate electrode 30 in the base layer 24. Further, an electronic current flows between the drain electrode 11 and the source electrode 12 through the drain layer 21, the N-type pillar layer 22, the channel, and the source layer 25.

When the potential of the gate electrode 30 becomes a potential lower than the threshold value, the channel is cut off, and the semiconductor device gets into the OFF state. During the OFF state, the depletion layer spreads from the P-N junction between the base layer 24 and the N-type pillar layer 22, and the P-N junction between the P-type pillar layer 23 and the N-type pillar layer 22, and thus, the breakdown voltage of the semiconductor device is maintained.

In the super junction structure, it is possible that CIB (Charge ImBalance) breakdown due to the charge imbalance is caused depending on the cut position of the end, and the design breakdown voltage cannot be obtained.

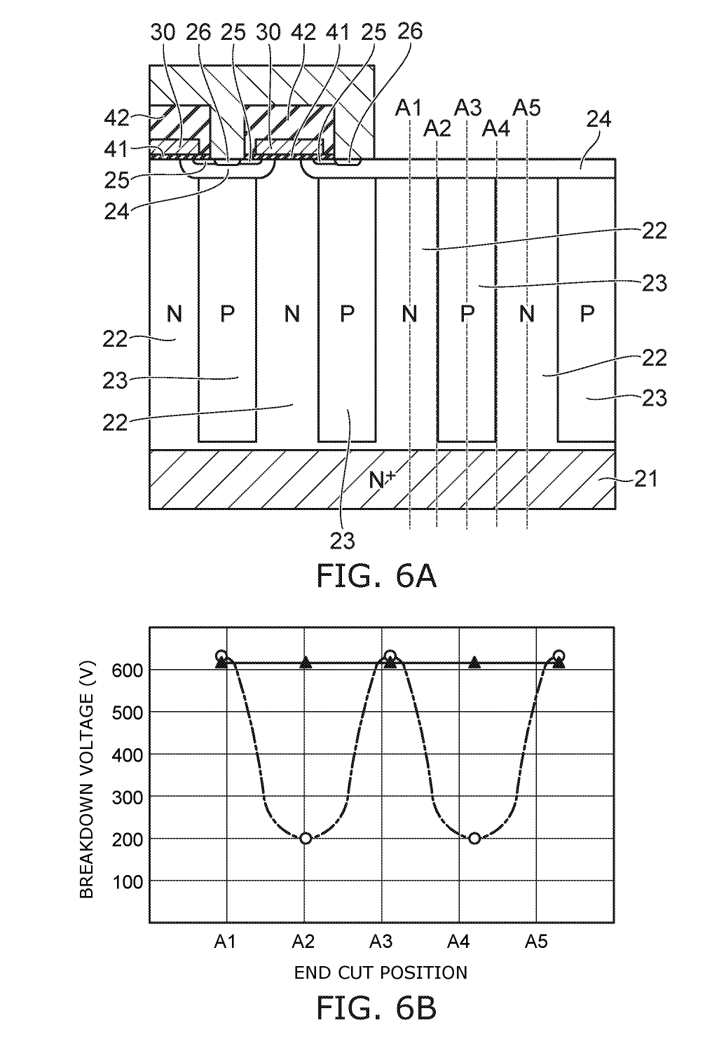

FIG. 6A shows a model used for the breakdown voltage simulation of the super junction structure, FIG. 6B is a graph showing a tendency of the end-cut-position dependency of the breakdown voltage in the model shown in FIG. 6A.

The horizontal axis of the graph of FIG. 6B represents the end cut positions A1, A2, A3, A4 and A5, and these positions A1, A2, A3, A4 and A5 represent the cut positions indicated by the dotted lines in FIG. 6A. The vertical axis represents the breakdown voltage (V).

In the structure shown in FIG. 6A, the breakdown voltage variation with the difference in the end cut position is great as indicated by the dashed-dotted line in the graph of FIG. 6B. In the case of A2, A4, namely the case in which cutting is performed at the boundary between the N-type pillar layer 22 and the P-type pillar layer 23, the breakdown voltage rapidly drops.

In contrast, according to the embodiment, as shown in FIG. 1, the semiconductive film 62 is formed on the side surface (or the side surface of the N-type pillar layer 22) of the P-type pillar layer 23 at the chip end via the insulating film 61, and the semiconductive film 62 is electrically connected to the drain electrode 11 and the source electrode 12. Therefore, a weak current flows between the drain electrode 11 and the source electrode 12 via the semiconductive film 62. The current flowing through the semiconductive film 62 forms a vertically even potential distribution on the side surface of the chip end.

In FIG. 1, the equipotential lines are shown as the dotted lines. For example, 600 V is applied between the drain electrode 11 and the source electrode 12, and the equipotential lines shown in FIG. 1 represent the equipotential lines of 100 V, 200 V, 300 V, 400 V and 500 V in sequence from the source electrode 12 side.

These equipotential lines respectively converge on the positions of the equipotential lines generated in the semiconductive film 62. Therefore, the vertically even potential distribution is formed in the end, and the high breakdown voltage can be maintained irrespective of the cut position as represented by the solid line in the simulation result shown in FIG. 6B. Wherever in the super junction structure the cutting is performed, the breakdown voltage does not drop rapidly.

Further, there is a concern over the problem that the external charge such as movable ions included in the resin 50 of the packaging curves the electric field in the end to increase the leak at high temperature. However, according to the embodiment, it is possible for the semiconductive film 62 to block the influence of the external charge.

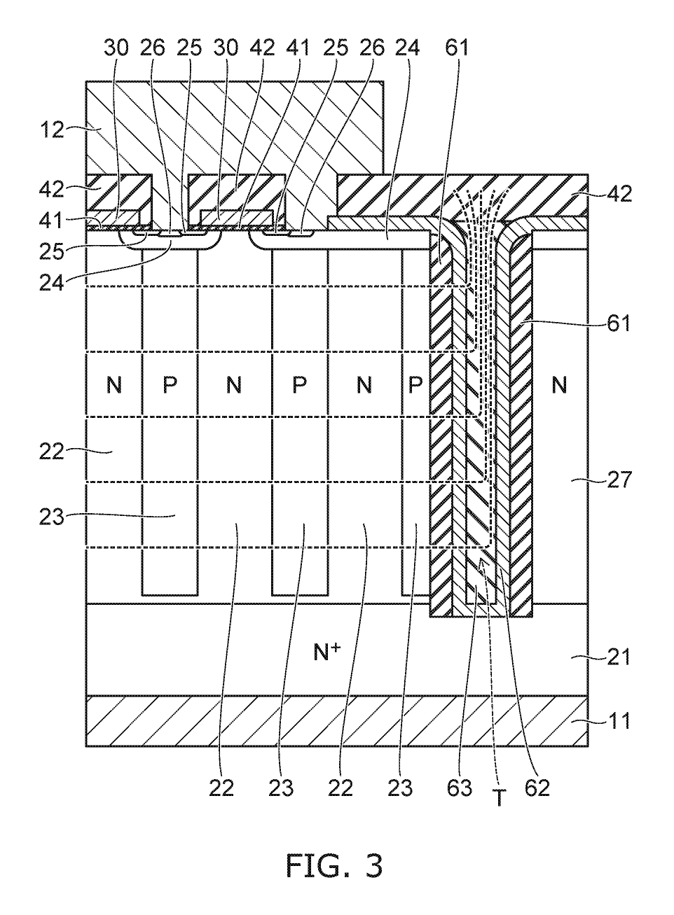

FIG. 3 is a schematic cross-sectional view of another example of the semiconductor device according to the embodiment.

The trench T extending in the vertical direction to reach the drain layer 21 is formed in the semiconductor layer on the drain layer 21. The insulating film 61 is conformally formed along the sidewall and the bottom of the trench T. Subsequently, the insulating film 61 formed on the bottom of the trench T is removed using, for example, an RIE method, and then the semiconductive film 62 is conformally formed in the trench T along the side surface of the insulating film 61, and the bottom of the trench T. The lower end part of the semiconductive film 62 has contact with the drain layer 21 in the bottom of the trench T.

Further, the inside of the semiconductive film 62 in the trench T is filled with an insulating member (insulator) 63. The insulating member 63 is, for example, a silicon oxide film. On the insulating film 61, the semiconductive film 62, and the insulating member 63 in the trench T, there is formed an inter-layer insulating film 42.

Outside the trench T, there is provided an N-type layer 27 having the same conductivity type as the drain layer 21 as a sixth semiconductor layer provided on the drain layer 21.

In the structure shown in FIG. 3, the semiconductive film 62 is formed on the side surface (or the side surface of the N-type pillar layer 22) of the P-type pillar layer 23 at the chip end via the insulating film 61, and the semiconductive film 62 is electrically connected to the drain electrode 11 and the source electrode 12. Therefore, a weak current flows between the drain electrode 11 and the source electrode 12 via the semiconductive film 62. The current flowing through the semiconductive film 62 forms a vertically even potential distribution on the side surface of the chip end.

In FIG. 3, the equipotential lines are shown as the dotted lines. For example, 600 V is applied between the drain electrode 11 and the source electrode 12, and the equipotential lines shown in FIG. 3 represent the equipotential lines of 100 V, 200 V, 300 V, 400 V and 500 V in sequence from the source electrode 12 side.

These equipotential lines respectively converge on the positions of the equipotential lines generated in the semiconductive film 62. Therefore, the vertically even potential distribution is formed in the end, and the high breakdown voltage can be maintained irrespective of the cut position as represented by the solid line in the simulation result shown in FIG. 6B. Wherever in the super junction structure the cutting is performed, the breakdown voltage does not drop rapidly.

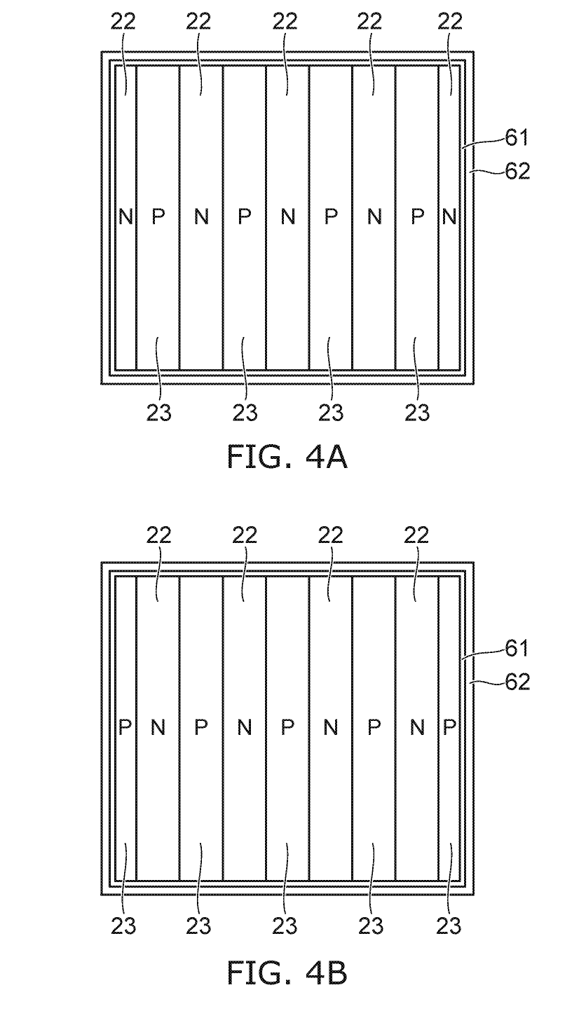

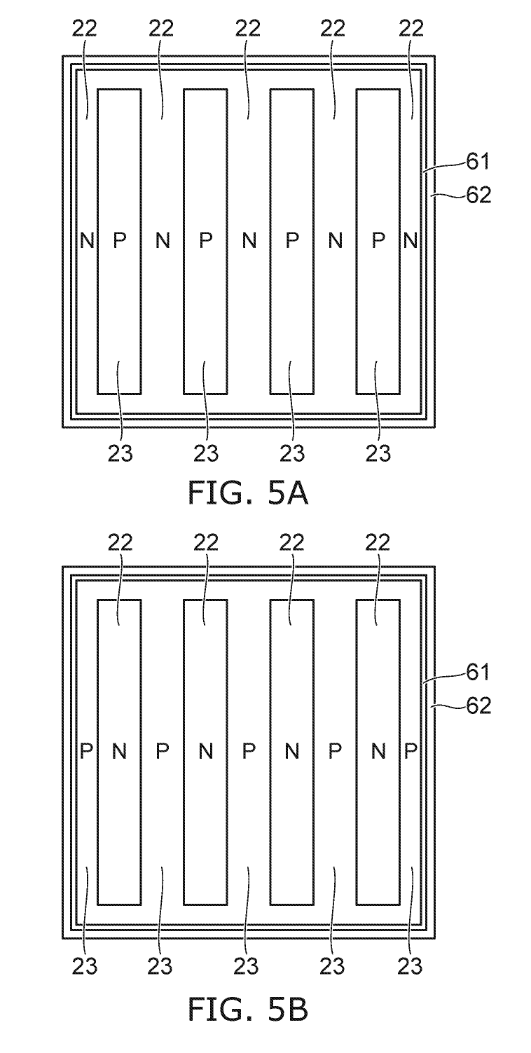

FIG. 4A through FIG. 5B are each a schematic plan view showing another example of a planar layout of the super junction structure.

FIG. 4A shows an example of performing the cutting in the N-type pillar layer 22 in the both ends in the periodic arrangement direction of the N-type pillar layer 22 and the P-type pillar layer 23.

FIG. 4B shows an example of performing the cutting in the P-type pillar layer 23 in the both ends in the periodic arrangement direction of the N-type pillar layer 22 and the P-type pillar layer 23.

FIG. 5A shows an example of performing the cutting in the N-type pillar layer 22 in the both ends in the periodic arrangement direction of the N-type pillar layer 22 and the P-type pillar layer 23. The N-type pillar layer 22 in the end is formed continuously in the direction along the periodic arrangement direction of the super junction structure, and surrounds the super junction structure.

FIG. 5B shows an example of performing the cutting in the P-type pillar layer 23 in the both ends in the periodic arrangement direction of the N-type pillar layer 22 and the P-type pillar layer 23. The P-type pillar layer 23 in the end is formed continuously in the direction along the periodic arrangement direction of the super junction structure, and surrounds the super junction structure.

Although in the embodiment described hereinabove, there is illustrated the semiconductor device having the MOSFET structure, the semiconductor device having the IGBT (Insulated Gate Bipolar Transistor) structure can also be adopted. The semiconductor device having the IGBT structure is provided with, for example, a P⁺-type layer (a collector layer) between the electrode 11 and the N⁺-type layer 21 shown in FIGS. 1, 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A semiconductor device comprising:
a first electrode;
a second electrode;
a first semiconductor layer having a first conductivity type and provided on the first electrode;
a plurality of second semiconductor layers having the first conductivity type and provided on the first semiconductor layer, the plurality of second semiconductor layers extending in a vertical direction connecting the first electrode and the second electrode;
a plurality of third semiconductor layers having a second conductivity type, the plurality of third semiconductor layers extending in the vertical direction on the first semiconductor layer, and adjacent to the plurality of second semiconductor layers in a lateral direction crossing the vertical direction;
a fourth semiconductor layer having the second conductivity type and provided on one of the plurality of third semiconductor layers;
a fifth semiconductor layer having the first conductivity type and provided on a surface of the fourth semiconductor layer, the fifth semiconductor layer connected to the second electrode;
a gate electrode opposed to the fourth semiconductor layer;
a gate insulating film provided between the fourth semiconductor layer and the gate electrode;
an insulating film provided on a side surface of a second semiconductor layer located at an end in the lateral direction of the plurality of second semiconductor layers, or a side surface of a third semiconductor layer located at an end in the lateral direction of the plurality of third semiconductor layers; and
a semiconductive film provided on a side surface of the insulating film, the semiconductive film electrically connected to the first electrode and the second electrode, the semiconductive film having a resistivity higher than a resistivity of one of the plurality of second semiconductor layers and a resistivity of one of the plurality of third semiconductor layers, and lower than a resistivity of the insulating film,
the insulating film being provided between the semiconductive film and one of the second semiconductor layer located at the end or the third semiconductor layer located at the end,
the semiconductive film not contacting the second semiconductor layer and the third semiconductor layer.

2. The device according to claim 1, wherein the semiconductive film has contact with the first semiconductor layer.

3. The device according to claim 1, wherein
the fourth semiconductor layer has contact with the second electrode, and
the semiconductive film has contact with the fourth semiconductor layer.

4. The device according to claim 1, wherein the insulating film continuously surrounds a region where the second semiconductor layers and the third semiconductor layers are disposed.

5. The device according to claim 1, wherein the semiconductive film continuously surrounds a region where the second semiconductor layers and the third semiconductor layers are disposed.

6. The device according to claim 1, wherein the semiconductive film is a silicon nitride film.

7. The device according to claim 1, wherein the semiconductive film is a polycrystalline silicon film.

8. The device according to claim 1, wherein the insulating film is a silicon oxide film.

9. The device according to claim 1, further comprising:
resin provided on a side surface of the semiconductive film.

10. The device according to claim 1, wherein
the insulating film is provided on a sidewall of a trench extending in the vertical direction to reach the first semiconductor layer, and
the semiconductive film is provided on a side surface of the insulating film in the trench.

11. The device according to claim 10, further comprising:
a sixth semiconductor layer provided outside the trench and on the first semiconductor layer.

12. The device according to claim 11, wherein the sixth semiconductor layer is a first conductivity type semiconductor layer.

13. The device according to claim 10, further comprising:
an insulator provided inside the semiconductive film in the trench.

14. The device according to claim 13, wherein the insulator is a silicon oxide film.

15. The device according to claim 1, wherein a first conductivity type impurity concentration of the first semiconductor layer is higher than a first conductivity type impurity concentration of one of the plurality of second semiconductor layers.

16. The device according to claim 1, wherein a first conductivity type impurity concentration of the fifth semiconductor layer is higher than a first conductivity type impurity concentration of one of the plurality of second semiconductor layers.

17. The device according to claim 1, wherein the fourth semiconductor layer on a termination side extends to an end of the device.
